(19) United States
(12) Patent Application Publication
(10) Pub. No.: US 2021/0375953 A1
(43) Pub. Date: Dec. 2, 2021

(54) FLEXIBLE DISPLAY PANEL WITH BENDING-RESISTANT SIGNAL LINES

(71) Applicant: WUHAN CHINA STAR OPTOELECTRONICS SEMICONDUCTOR DISPLAY TECHNOLOGY CO., LTD., Wuhan (CN)

(72) Inventor: Jinrong Zhao, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/336,693

(22) PCT Filed: Feb. 12, 2019
(86) PCT No.: PCT/CN2019/074842

§ 371 Date: Mar. 26, 2019

(30) Foreign Application Priority Data
Oct. 26, 2018 (CN) 201811260326.2

(51) Int. Cl. H01L 27/12

(52) U.S. Cl. CPC H01L 27/1244

(57) ABSTRACT

A flexible display panel has a plurality of signal lines. At least one of the signal lines includes a first metal layer, a first planarization layer and a second metal layer. The first metal layer includes a plurality of metal members arranged at intervals. The first planarization layer is disposed on the first metal layer and includes a plurality of first through holes, and the first through holes are in one-to-one correspondence to the metal members in terms of position in order to expose the metal members. The second metal layer is disposed on the first planarization layer, wherein the pattern of the second metal layer is wavy, and the second metal layer is connected to the metal members through the first through holes.

### FIELD OF DISCLOSURE

The present invention relates to a flexible display panel and in particular to a flexible display panel with bending-resistant signal lines.

### BACKGROUND OF DISCLOSURE

Referring to FIG. 1, in an existing flexible display panel, from a fan-out area to an active area, GE metal lines 90 such as gate lines, reset lines and emission control lines transfer signals in a horizontal direction, and SE metal lines 91 such as data lines and power lines (ELVDD, ELVSS) transfer signals in a vertical direction.

The existing GE metal lines 90 or SE metal lines 91 are generally shaped in an elongated strip-shaped rectangle. When the display panel is being bent, this shape cannot effectively relive stress and hinder crack extension. When the stress is greater than the tolerance of metal, it is likely to cause cracking, resulting in larger impedance or breakage of metal lines. Cracks will further extend to other film layers or other functional areas during the folding process, so that the probability of undesirable effects will be increased and the service life of devices will be shortened.

Hence, it is necessary to provide a flexible display panel with bending-resistant signal lines to overcome the problems existing in the conventional technology.

### SUMMARY OF DISCLOSURE

In view of the defects in the prior art, a main objective of the present disclosure is to provide a flexible display panel having signal lines with higher stress tolerance, which can effectively relieve stress and hinder crack extension and thus prolong the service life of devices.

To achieve the above objective of the present disclosure, the present disclosure provides a flexible display panel having a plurality of signal lines, wherein at least one of the signal lines includes: a first metal layer including a plurality of metal members arranged at intervals; a first planarization layer which is disposed on the first metal layer and includes a plurality of first through holes, the first through holes being in one-to-one correspondence to the metal members in terms of position in order to expose the metal members; wherein the first planarization layer is an inorganic material layer; a second metal layer disposed on the first planarization layer, wherein a pattern of the second metal layer is wavy, and the second metal layer is connected to the metal members through the first through holes; and a second planarization layer disposed on the second metal layer; wherein the second planarization layer is an organic material layer.

In one embodiment of the present disclosure, the first planarization layer further includes a plurality of second through holes which run through an upper surface and a lower surface of the first planarization layer;

the second metal layer includes a plurality of vias which are correspondingly communicated with the second through holes, respectively; and

the second planarization layer extends to a bottom of the first planarization layer through the vias and the second through holes.

In one embodiment of the present disclosure, a pattern of each of the metal members in the first metal layer is rectangular or square, and the pattern of the second metal layer has a sine-wave shape.

In one embodiment of the present disclosure, the first metal layer is a molybdenum layer or a composite layer of a molybdenum layer and an aluminum neodymium alloy layer, and the second metal layer is a composite layer of a titanium layer and an aluminum layer.

In one embodiment of the present disclosure, the first metal layer includes two molybdenum layers and an aluminum neodymium alloy layer disposed between the two molybdenum layers, and the second metal layer includes two titanium layers and an aluminum layer disposed between the two titanium layers.

In one embodiment of the present disclosure, at least two of the second through holes are formed at intervals between two adjacent first through holes.

The present disclosure further provides a flexible display panel, having a plurality of signal lines, wherein at least one of the signal lines includes: a first metal layer including a plurality of metal members arranged at intervals; a first planarization layer which is disposed on the first metal layer and includes a plurality of first through holes, the first through holes being in one-to-one correspondence to the metal members in terms of position in order to expose the metal members; and a second metal layer disposed on the first planarization layer, wherein a pattern of the second metal layer is wavy, and the second metal layer is connected to the metal members through the first through holes.

In one embodiment of the present disclosure, each of the signal lines further includes a second planarization layer disposed on the second metal layer.

In one embodiment of the present disclosure, the first planarization layer further includes a plurality of second through holes which run through an upper surface and a lower surface of the first planarization layer; the second metal layer includes a plurality of vias which are correspondingly communicated with the second through holes, respectively; and the second planarization layer extends to a bottom of the first planarization layer through the vias and the second through holes.

In one embodiment of the present disclosure, each of the signal lines further includes a second planarization layer disposed between the second metal layer and the first planarization layer.

In one embodiment of the present disclosure, the first planarization layer further includes a plurality of second through holes which run through an upper surface and a lower surface of the first planarization layer; and the second planarization layer extends to a bottom of the first planarization layer through the second through holes, and the second planarization layer includes a plurality of third through holes which are correspondingly communicated with the first through holes in the first planarization layer, respectively, so that the second metal layer is connected to the metal members through the third through holes and the first through holes.

In one embodiment of the present disclosure, a pattern of each of the metal members in the first metal layer is rectangular or square, and the pattern of the second metal layer has a sine-wave shape.

In one embodiment of the present disclosure, the first metal layer is a molybdenum layer or a composite layer of a molybdenum layer and an aluminum neodymium alloy layer, and the second metal layer is a composite layer of a titanium layer and an aluminum layer.

In one embodiment of the present disclosure, the first metal layer includes two molybdenum layers and an aluminum neodymium alloy layer disposed between the two molybdenum layers, and the second metal layer includes two titanium layers and an aluminum layer disposed between the two titanium layers.

In one embodiment of the present disclosure, at least two of the second through holes are formed at intervals between two adjacent first through holes.

In the present disclosure, signal lines of the flexible display panel are mainly manufactured by interconnecting upper and lower metal layers, wherein the metal layer in the lower layer is divided into a plurality of short strip-shaped rectangular or square metal members arranged at intervals, and a planarization layer is disposed between the two adjacent metal layers; the pattern of the metal layer in the upper layer is wavy and may be connected to the metal members of the metal layer in the lower layer through the through holes in the planarization layer, and other through holes of the planarization layer are filled with organic matter. The wavy pattern design of the metal layer in the upper layer can effectively relieve stress, and the organic matter in the through holes in the planarization layer can improve the stress tolerance of the inorganic planarization layer between the two metal layers, so that the service life of the devices is prolonged.

### DESCRIPTION OF DRAWINGS

FIG. 1 is a schematic view of metal lines of an existing display panel.

FIG. 2 is a schematic planar view of signal lines of a flexible display panel according to an embodiment of the present invention.

FIG. 3A is a cross-sectional view of signal lines of the flexible display panel according to an embodiment of the present invention.

FIG. 3B is a cross-sectional view of signal lines of the flexible display panel according to another embodiment of the present invention.

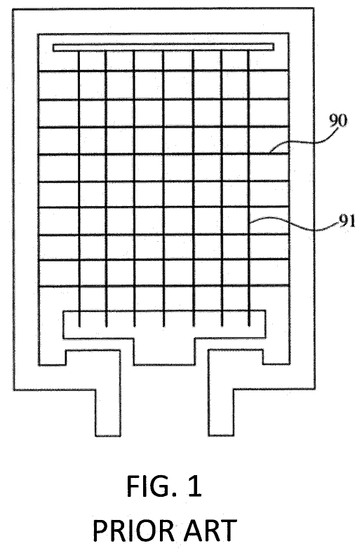

### DETAILED DESCRIPTION OF PREFERRED EMBODIMENTS

The foregoing objects, features and advantages adopted by the present disclosure can be best understood by referring to the following detailed description of the preferred embodiments and the accompanying drawings. Furthermore, the directional terms described in the present disclosure, such as upper, lower, front, rear, left, right, inner, outer, side, etc., are only directions referring to the accompanying drawings, so that the used directional terms are used to describe and understand the present disclosure, but the present disclosure is not limited thereto.

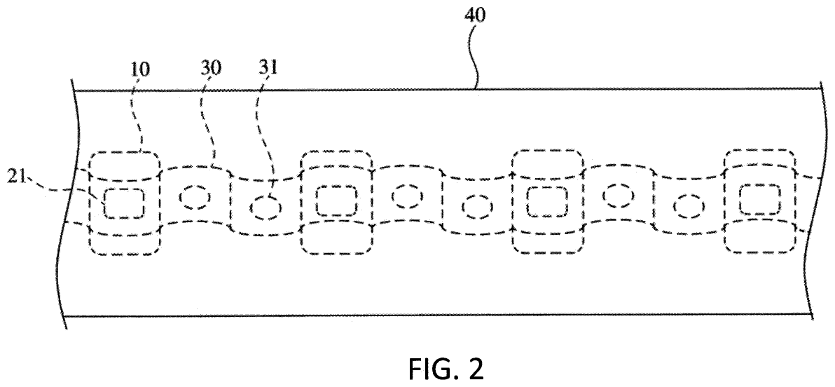

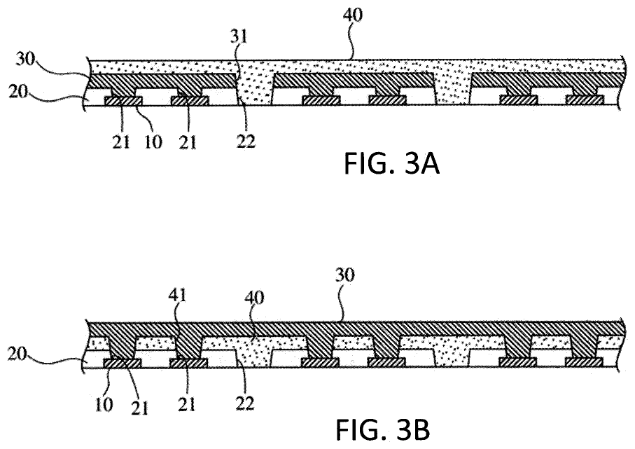

Referring to FIG. 2 and FIG. 3A, FIG. 2 is a schematic planar view of signal lines of a flexible display panel according to an embodiment of the present invention, and FIG. 3A is a sectional view of signal lines of the flexible display panel according to an embodiment of the present invention.

The signal lines of the flexible display panel in the present invention are preferably applicable to, for example, ESD protective lines, dummy metal lines or lines having low impedance requirements in a fan-out area of a flexible display panel. Each of the signal lines mainly includes a first metal layer 10, a first planarization layer 20 and a second metal layer 30.

As shown in FIG. 2 and FIG. 3A, the first metal layer 10 includes a plurality of metal members arranged at intervals. In an embodiment, the pattern of each of the metal members of the first metal layer 10 is rectangular or square, or approximately rectangular or square. Further, in an embodiment, the first metal layer 10 may be a molybdenum layer or a composite layer of a molybdenum layer and an aluminum neodymium alloy layer. For example, when the first metal layer 10 may be a composite layer of a molybdenum layer and an aluminum neodymium alloy layer, it is possible that the first metal layer 10 includes a molybdenum layer and an aluminum neodymium alloy layer, or it is also possible that the first metal layer 10 includes two molybdenum layers and an aluminum neodymium alloy layer disposed between the two molybdenum layers. In this way, the impedance of wiring may be effectively reduced.

As shown in FIG. 2 and FIG. 3A, the first planarization layer 20 is disposed on the first metal layer 10 and includes a plurality of first through holes 21. The first planarization layer 20 may further include a plurality of second through holes 22. The first through holes 21 are in one-to-one correspondence to the metal members of the first metal layer 10 in terms of position in order to expose the metal members. As shown in FIG. 3A, the second through holes 22 run through an upper surface and a lower surface of the first planarization layer 20. In this embodiment, the first planarization layer 20 is an inorganic material layer. In an embodiment, in the first planarization layer 20, at least two of the second through holes 22 are formed at intervals between two adjacent first through holes 21, but it is not limited thereto.

As shown in FIG. 3A, the second metal layer 20 is disposed on the first planarization layer 20; and further, as shown in FIG. 2, the pattern of the second metal layer 30 is wavy, for example, preferably sine wavy. The second metal layer 30 is connected to the metal members 10 through the first through holes 21, so that signal lines manufactured by interconnecting the upper and lower metal layers are formed. The signal lines formed by the wavy pattern design of the second metal layer 30 can effectively relieve the stress applied to the display panel during bending, and can thus prolong the service life of the devices. In an embodiment, the second metal layer 30 may be a composite layer of a titanium layer and an aluminum layer. For example, the second metal layer 30 may include two titanium layers and an aluminum layer located between the two titanium layers.

As shown in FIG. 3A, in a preferred embodiment, each of the signal lines may further include a second planarization layer 40. In the embodiment of FIG. 3A, the second planarization layer 40 is disposed on the second metal layer 30, and the second planarization layer is preferably an organic material layer. In the embodiment shown in FIG. 3A, the second metal layer 30 further includes a plurality of vias 31. The vias 31 are correspondingly communicated with the second through holes 22 in the first planarization layer 20, respectively, so that the second planarization layer extends to the bottom of the first planarization layer 20 through the vias 31 and the second through holes 22.

In this way, the signal lines of the whole flexible display panel shown in FIG. 3A form a stacked structure including four layers, i.e., an organic layer (i.e., the second planarization layer), a metal layer (i.e., the second metal layer), an inorganic layer (i.e., the first planarization layer) and a metal layer (i.e., the first metal layer) from the top down, wherein the vias 31 in the second metal layer 30 and the second through holes 22 in the first planarization layer 20 are filled with the organic material forming the second planarization layer. In such a structure, the signal lines formed by the wavy pattern design of the second metal layer 30 can effectively relieve the stress applied to the display panel during bending; the vias 31 in the second metal layer 30 can be used for preventing small cracks in the metal layer to further extend to other parts of the metal layer, thereby avoiding the breakage of the whole metal layer and the functional failure; and, the organic material filled in the vias 31 and the second through holes 22 can effectively improve the stress tolerance of the inorganic matter between the two metal layers, so that the further extension of cracks in the inorganic layer is hindered. In other words, since the organic material forming the second planarization layer 40 is relatively elastic and has a function of buffering, the organic material can buffer and offset the stress, so that the stress will not be accumulated on the structural defects (e.g., cracks) of the inorganic material layer (the first planarization layer 20) and thus will not result in the breakage of the whole signal lines.

Further, referring to FIG. 3B, FIG. 3B is a sectional view of signal lines of the flexible display panel according to another embodiment of the present invention. This embodiment mainly differs from the embodiment of FIG. 3A in that the second planarization layer 40 and the second metal layer 30 are arranged in a different order.

As shown in FIG. 3B, the second planarization layer 40 is disposed on the first planarization layer 20, and the second metal layer 30 is then disposed on the second planarization layer 40, so that the second planarization layer 40 is disposed between the second metal layer 30 and the first planarization layer 20.

More specifically, in this embodiment, there may be no vias 31 formed on the second metal layer 30. The second planarization layer 40 directly extends to the bottom of the first planarization layer 20 through the second through holes 22 in the first planarization layer 20. In this embodiment, the second planarization layer 40 includes a plurality of third through holes 41, wherein the third through holes 41 are correspondingly communicated with the first through holes 21 in the first planarization layer 20, respectively, so that the second metal layer 30 is connected to the metal members in the first metal layer 10 through the third through holes 41 and the first through holes 21.

With the above structure, the signal lines formed by the wavy pattern design of the second metal layer 30 can effectively relieve the stress applied to the display panel during bending; and, the second planarization layer 40 formed from the organic material is located between the first metal layer 10 and the second metal layer 30, and the second through holes 22 in the first planarization layer 20 are also filled with the organic material forming the second planarization layer 40, so that the stress tolerance of the inorganic matter between the two metal layers can also be effectively improved and the further extension of cracks in the inorganic layer can be hindered.

In conclusion, compared with the prior art, in the present invention, signal lines of the flexible display panel are mainly manufactured by interconnecting upper and lower metal layers, wherein the first metal layer in the lower layer is divided into a plurality of short strip-shaped rectangular or square metal members arranged at intervals, and an inorganic planarization layer (i.e., the first planarization layer) is disposed between the two adjacent metal layers; and, the pattern of the second metal layer in the upper layer is wavy, the second metal layer may be connected to the metal members of the first metal layer in the lower layer through the through holes in the inorganic planarization layer, and other through holes (i.e., second through holes) of the inorganic planarization layer are filled with organic matter (i.e., an extended portion of the second organic planarization layer). The wavy pattern design of the second metal layer in the upper layer can effectively relieve stress, and the organic matter in the through holes in the inorganic planarization layer can improve the stress tolerance of the inorganic planarization layer between the two metal layers, so that the service life of the devices is prolonged.

In conclusion, although the present disclosure has been described with reference to the preferred embodiment thereof, it is apparent to those skilled in the art that a variety of modifications and changes may be made without departing from the scope of the present disclosure which is intended to be defined by the appended claims.

What is claimed is:

1. A flexible display panel, comprising a plurality of signal lines, wherein at least one of the signal lines comprises:
a first metal layer including a plurality of metal members arranged at intervals;
a first planarization layer which is disposed on the first metal layer and comprises a plurality of first through holes, the first through holes being in one-to-one correspondence to the metal members in terms of position in order to expose the metal members; wherein the first planarization layer is an inorganic material layer;
a second metal layer disposed on the first planarization layer, wherein a pattern of the second metal layer is wavy, and the second metal layer is connected to the metal members through the first through holes; and
a second planarization layer disposed on the second metal layer; wherein the second planarization layer is an organic material layer.

2. The flexible display panel according to claim 1, wherein the first planarization layer further comprises a plurality of second through holes which run through an upper surface and a lower surface of the first planarization layer;
the second metal layer comprises a plurality of vias which are correspondingly communicated with the second through holes, respectively; and
the second planarization layer extends to a bottom of the first planarization layer through the vias and the second through holes.

3. The flexible display panel according to claim 1, wherein a pattern of each of the metal members in the first metal layer is rectangular or square, and the pattern of the second metal layer has a sine-wave shape.

4. The flexible display panel according to claim 1, wherein the first metal layer is a molybdenum layer or a composite layer of a molybdenum layer and an aluminum neodymium alloy layer, and the second metal layer is a composite layer of a titanium layer and an aluminum layer.

5. The flexible display panel according to claim 4, wherein the first metal layer includes two molybdenum layers and an aluminum neodymium alloy layer disposed between the two molybdenum layers, and the second metal layer includes two titanium layers and an aluminum layer disposed between the two titanium layers.

6. The flexible display panel according to claim 2, wherein at least two of the second through holes are formed at intervals between two adjacent first through holes.

7. A flexible display panel, comprising a plurality of signal lines, wherein at least one of the signal lines comprises:
a first metal layer including a plurality of metal members arranged at intervals;
a first planarization layer which is disposed on the first metal layer and comprises a plurality of first through holes, the first through holes being in one-to-one correspondence to the metal members in terms of position in order to expose the metal members; and
a second metal layer disposed on the first planarization layer, wherein a pattern of the second metal layer is wavy, and the second metal layer is connected to the metal members through the first through holes.

8. The flexible display panel according to claim 7, wherein each of the signal lines further comprises a second planarization layer disposed on the second metal layer.

9. The flexible display panel according to claim 8, wherein the first planarization layer further comprises a plurality of second through holes which run through an upper surface and a lower surface of the first planarization layer;
the second metal layer comprises a plurality of vias which are correspondingly communicated with the second through holes, respectively; and
the second planarization layer extends to a bottom of the first planarization layer through the vias and the second through holes.

10. The flexible display panel according to claim 7, wherein each of the signal lines further comprises a second planarization layer disposed between the second metal layer and the first planarization layer.

11. The flexible display panel according to claim 10, wherein the first planarization layer further includes a plurality of second through holes which run through an upper surface and a lower surface of the first planarization layer; and
the second planarization layer extends to a bottom of the first planarization layer through the second through holes, and the second planarization layer comprises a plurality of third through holes which are correspondingly communicated with the first through holes in the first planarization layer, respectively, so that the second metal layer is connected to the metal members through the third through holes and the first through holes.

12. The flexible display panel according to claim 7, wherein the first planarization layer is an inorganic material layer and the second planarization layer is an organic material layer.

13. The flexible display panel according to claim 7, wherein a pattern of each of the metal members in the first metal layer is rectangular or square, and the pattern of the second metal layer has a sine-wave shape.

14. The flexible display panel according to claim 7, wherein the first metal layer is a molybdenum layer or a composite layer of a molybdenum layer and an aluminum neodymium alloy layer, and the second metal layer is a composite layer of a titanium layer and an aluminum layer.

15. The flexible display panel according to claim 14, wherein the first metal layer includes two molybdenum layers and an aluminum neodymium alloy layer disposed between the two molybdenum layers, and the second metal layer includes two titanium layers and an aluminum layer disposed between the two titanium layers.

16. The flexible display panel according to claim 9, wherein at least two of the second through holes are formed at intervals between two adjacent first through holes.

17. The flexible display panel according to claim 11, wherein at least two of the second through holes are formed at intervals between two adjacent first through holes.
